(19) United States
(12) Patent Application Publication
(10) Pub. No.: US 2021/0238746 A1
(43) Pub. Date: Aug. 5, 2021

(54) SHOWERHEAD ASSEMBLY

(71) Applicant: APPLIED MATERIALS, INC., Santa Clara, CA (US)

(72) Inventors: TIMOTHY JOSEPH FRANKLIN, CAMPBELL, CA (US); JOSEPH F. SOMMERS, SAN JOSE, CA (US); CARLATON WONG, SUNNYVALE, CA (US); REYN WAKABAYASHI, SAN JOSE, CA (US); Joseph Frederick BEHNKE, San Jose, CA (US)

(21) Appl. No.: 16/823,898

(22) Filed: Mar. 19, 2020

Related U.S. Application Data
(63) Continuation-in-part of application No. 16/786,292, filed on Feb. 10, 2020.
Application No. 16/786,292 is a continuation-in-part of application No. 16/780,855, filed on Feb. 3, 2020.

(51) Int. Cl. C23C 16/455

(52) U.S. Cl. CPC C23C 16/45565

(57) ABSTRACT

A showerhead assembly, and method of forming thereof is provided. The apparatus, for example, includes a gas distribution plate comprising an inner portion and an outer portion, the inner portion made from single crystal silicon (Si) and the outer portion made from one of single crystal Si or polysilicon (poly-Si), wherein a bonding layer is provided on a back surface of at least one of the inner portion or outer portion; a backing plate formed from silicon (Si) and silicon carbide (SiC) as a major component thereof, wherein the backing plate is bonded to at least one of the back surface of at least one of the inner portion or outer portion of the gas distribution plate.

### CROSS-REFERENCE TO RELATED APPLICATIONS

The present application is a continuation-in-part of U.S. patent application Ser. No. 16/786,292, filed on Feb. 10, 2020, which is a continuation-in-part of U.S. patent application Ser. No. 16/780,855, filed on Feb. 3, 2020, the entire contents of each of these applications is herein incorporated by reference.

### FIELD

Embodiments of the present disclosure generally relate to showerhead assemblies, and more particularly, to showerhead assemblies for use in substrate processing systems.

### BACKGROUND

Conventional showerhead assemblies configured for use with process chambers, such as those used in microelectronic device fabrication, for example, typically include a gas distribution plate that has a backing plate coupled thereto. For example, the backing plate can be coupled to the gas distribution plate using one or more connecting devices, e.g., bolts, screws, clamps, etc. While such connecting devices are suitable for connecting the backing plate to the gas distribution plate, after extended use of the gas distribution plate assemblies, the torque and moment forces present at the connecting devices can sometimes compromise the connection between the gas distribution plate and the backing plate, which, in turn, can result in the gas distribution plate assemblies not operating as intended.

Accordingly, improved showerhead assemblies and methods of manufacturing the same are described herein.

### SUMMARY

In at least some embodiments, for example, a showerhead assembly, comprises a gas distribution plate comprising an inner portion and an outer portion, the inner portion made from single crystal silicon (Si) and the outer portion made from one of single crystal Si or polysilicon (poly-Si), wherein a bonding layer is provided on a back surface of at least one of the inner portion or outer portion; and a backing plate formed from silicon (Si) and silicon carbide (SiC) as a major component thereof, wherein the backing plate is bonded to at least one of the back surface of at least one of the inner portion or outer portion of the gas distribution plate.

The inner portion and outer portion can be a homogeneous unitary body made from single crystal silicon Si. The bonding layer can include at least one concentric ring seated within a corresponding concentric groove on a back surface of at least one of the inner portion or outer portion. The bonding layer can be made of aluminum silicon alloy or aluminum, with a percentage of titanium (Ti). The percentage of Ti can range from about 0.1% to about 10%. A coefficient of thermal expansion (CTE) between the gas distribution plate and the backing plate can be about 2 to about 7.

In at least some embodiments, a process chamber comprises a showerhead assembly that comprises a gas distribution plate comprising an inner portion and an outer portion, the inner portion made from single crystal silicon (Si) and the outer portion made from one of single crystal Si or polysilicon (poly-Si), wherein a bonding layer is provided on a back surface of at least one of the inner portion or outer portion; and a backing plate formed from silicon (Si) and silicon carbide (SiC) as a major component thereof, wherein the backing plate is bonded to at least one of the back surface of at least one of the inner portion or outer portion of the gas distribution plate.

The inner portion and outer portion can be a homogeneous unitary body made from single crystal silicon Si. The bonding layer can include at least one concentric ring seated within a corresponding concentric groove on a back surface of at least one of the inner portion or outer portion. The bonding layer can be made of aluminum silicon alloy or aluminum, with a percentage of titanium (Ti). The percentage of Ti can range from about 0.1% to about 10%. A coefficient of thermal expansion (CTE) between the gas distribution plate and the backing plate can be about 2 to about 7.

In at least some embodiments, a method of forming a showerhead assembly comprises depositing a bonding layer on a back surface of a gas distribution plate made from at least one of single crystal silicon (Si) or polysilicon (poly-Si); and bonding a backing plate formed from silicon (Si) and silicon carbide (SiC) as a major component thereof to the back surface of the gas distribution plate.

The gas distribution plate comprises an inner portion and outer portion, and wherein the inner portion and outer portion are a homogeneous unitary body made from single crystal silicon Si. The bonding layer includes at least one concentric ring seated within a corresponding concentric groove on a back surface of at least one of the inner portion or outer portion. The bonding layer is made of aluminum silicon alloy or aluminum, with a percentage of titanium (Ti). The percentage of Ti ranges from about 0.1% to about 10%.

The method can further comprise, prior to bonding the backing plate to the back surface of the gas distribution plate, depositing a hard mask layer atop the back surface of the gas distribution plate.

The method can further comprise, after depositing the hard mask layer atop the back surface of the gas distribution plate and prior to bonding the backing plate to the back surface of the gas distribution plate, removing the hard mask layer.

The method can further comprise performing at least one of scanning acoustic microscopy (SAM) metrology, sonar scanning, or sonar imaging to examine the bond between the gas distribution plate and the backing plate.

Bonding the backing plate to the back surface of the gas distribution plate can comprise using a furnace process that provides temperatures from about 350 degree Celsius to about 750 degrees Celsius and introducing a back-flow gas while performing the furnace process.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a cross sectional view of a processing chamber, according to at least some embodiments of the present disclosure.

FIG. 2A is a side cutaway view of a gas distribution plate and backing plate of a showerhead assembly, according to at least some embodiments of the present disclosure.

FIG. 2B is a side cutaway view of the gas distribution plate of FIG. 2A, according to at least some embodiments of the present disclosure.

FIG. 2C is an exploded top isometric view of the gas distribution plate of FIG. 2A, according to at least some embodiments of the present disclosure.

FIG. 2D is a top elevation view of a ring body of a gas distribution plate, according to at least some embodiments of the present disclosure.

FIG. 3 is a flowchart of a method of manufacture of the gas distribution plate and backing plate of FIGS. 2A-2C, according to at least some embodiments of the present disclosure.

FIG. 4A is a top isometric view of a gas distribution plate of a showerhead assembly in cross-section, according to at least some embodiments of the present disclosure.

Nom FIG. 4B is an exploded view of the gas distribution plate of FIG. 4A, according to at least some embodiments of the present disclosure.

FIG. 5 is a flowchart of a method of manufacture of the gas distribution plate and backing plate of FIGS. 4A-4B, according to at least some embodiments of the present disclosure.

FIG. 6 is a side cutaway view of a gas distribution plate and backing plate of a showerhead assembly, according to at least some embodiments of the present disclosure.

FIG. 7 is a flowchart of a method of manufacture of the gas distribution plate and backing plate of FIG. 6, according to at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a showerhead assembly comprising a gas distribution plate including a connector bonded thereto, and method of manufacturing the same, are provided herein. More particularly, the gas distribution assemblies described herein include a gas distribution plate that includes an inner portion and an outer portion respectively made from single crystal silicon (Si) and single crystal Si or polysilicon (poly-Si). Additionally, one or both of the inner portion and outer portion have bonded thereon a connector formed of Si and varying quantities of silicon carbide (SiC). The bonded connector is used to connect the gas distribution plate to a backing plate of the showerhead assembly. Unlike conventional gas distribution plate assemblies that use one or more of bolts, screws, clamps, etc. to connect a backing plate to a gas distribution plate, the relatively strong bond provided between the connector and inner portion and/or outer portion maintains the gas distribution plate connected to the backing plate under the torque and moment forces that are present during operation of the showerhead assembly. Additionally, the bonded connector provides equal distribution of loading along the gas distribution plate. Additionally, a jacket that is coupled to the connector (e.g., ring body), allows the gas distribution plate to be removed from the backing plate for replacing the gas distribution plate (e.g., no debonding is required).

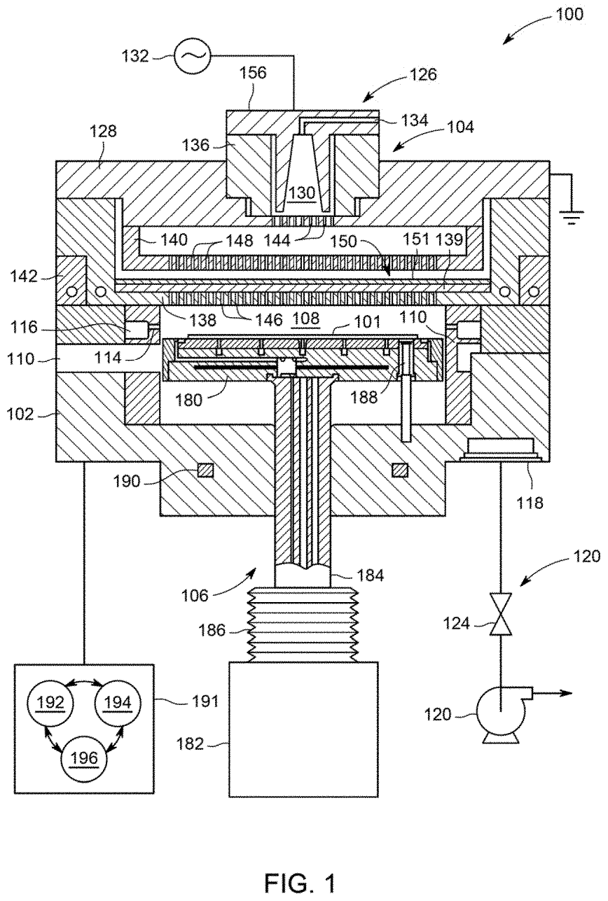

FIG. 1 is a cross sectional view of a processing chamber 100 having an improved showerhead assembly 150, according to at least one embodiment of the present disclosure. As shown, the processing chamber 100 is an etch chamber suitable for etching a substrate, such as substrate 101. Examples of processing chambers that may be adapted to benefit from the embodiments of the disclosure are Sym3® Processing Chamber, and Mesa™ Processing Chamber, commercially available from Applied Materials, Inc., located in Santa Clara, Calif. Other processing chambers, including those from other manufacturers, may be adapted to benefit from the embodiments of the disclosure.

The processing chamber 100 may be used for various plasma processes. In one embodiment, the processing chamber 100 may be used to perform dry etching with one or more etching agents. For example, the processing chamber may be used for ignition of plasma from a precursor CxFy (where x and y can be different allowed combinations), O₂, NF₃, or combinations thereof.

The processing chamber 100 includes a chamber body 102, a lid assembly 104, and a support assembly 106. The lid assembly 104 is positioned at an upper end of the chamber body 102. The support assembly 106 is disclosed in an interior volume 108, defined by the chamber body 102. The chamber body 102 includes a slit valve opening 110 formed in a sidewall thereof. The slit valve opening 110 is selectively opened and closed to allow access to the interior volume 108 by a substrate handling robot (not shown) for substrate transfer.

The chamber body 102 may further include a liner 112 that surrounds the support assembly 106. The liner 112 may be made of a metal such as (Al), a ceramic material, or any other process compatible material. In one or more embodiments, the liner 112 includes one or more apertures 114 and a pumping channel 116 formed therein that is in fluid communication with a vacuum port 118. The apertures 114 provide a flow path for gases into the pumping channel 116. The pumping channel 116 provides an egress for the gases within the processing chamber 100 to vacuum port 118.

A vacuum system 120 is coupled to the vacuum port 118. The vacuum system 120 may include a vacuum pump 122 and a throttle valve 124. The throttle valve 124 regulates the flow of gases through the processing chamber 100. The vacuum pump 122 is coupled to the vacuum port 118 disposed in the interior volume 108.

The lid assembly 104 includes at least two stacked components configured to form a plasma volume or cavity therebetween. In one or more embodiments, the lid assembly 104 includes a first electrode (“upper electrode”) 126 disposed vertically above a second electrode (“lower electrode”) 128. The first electrode 126 and the second electrode 128 confine a plasma cavity 130, therebetween. The first electrode 126 is coupled to a power source 132, such as an RF power supply. The second electrode 128 is connected to ground, forming a capacitor between the first electrode 126 and second electrode 128. The first electrode 126 is in fluid communication with a gas inlet 134 that is connected to a gas supply (not shown), which provides gas to the process chamber 100 via the gas inlet 134. The first end of the one or more gas inlets 134 opens into the plasma cavity 130.

The lid assembly 104 may also include an isolator ring 136 that electrically isolates the first electrode 126 from the second electrode 128. The isolator ring 136 may be made from aluminum oxide (AIO) or any other insulative, processing compatible, material.

The lid assembly 104 may also include showerhead assembly 150 and, optionally, a blocker plate 140. The showerhead assembly 150 includes a gas distribution plate 138, a backing (gas) plate 139, and a chill plate 151. The second electrode 128, the gas distribution plate 138, the chill plate 151, and the blocker plate 140 may be stacked and disposed on a lid rim 142, which is coupled to the chamber body 102.

The chill plate 151 is configured to regulate a temperature of the gas distribution plate 138 during processing. For example, the chill plate 151 may include one or more temperature control channels (not shown) formed therethrough such that a temperature control fluid may be provided therein to regulate the temperature of the gas distribution plate 138.

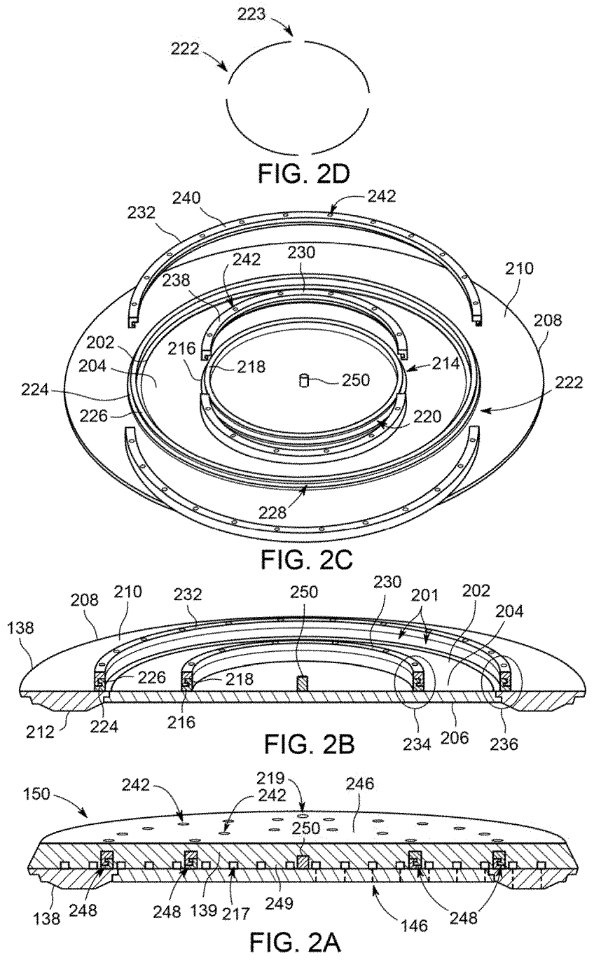

In one or more embodiments, the second electrode 128 may include a plurality of gas passages 144 formed beneath the plasma cavity 130 to allow gas from the plasma cavity 130 to flow therethrough. The backing plate 139 includes one of more gas passages 217 and one or more gas delivery channels 219 (see FIG. 2A, for example), thus allowing gas to flow from the one or more gas passages 217 and into the processing region. Similarly, the gas distribution plate 138 includes a plurality of apertures 146 configured to distribute the flow of gases therethrough. The blocker plate 140 may optionally be disposed between the second electrode 128 and the gas distribution plate 138. The blocker plate 140 includes a plurality of apertures 148 to provide a plurality of gas passages from the second electrode 128 to the gas distribution plate 138.

The support assembly 106 may include a support member 180. The support member 180 is configured to support the substrate 101 for processing. The support member 180 may be coupled to a lift mechanism 182 through a shaft 184, which extends through a bottom surface of the chamber body 102. The lift mechanism 182 may be flexibly sealed to the chamber body 102 by a bellows 186 that prevents vacuum leakage from around the shaft 184. The lift mechanism 182 allows the support member 180 to be moved vertically within the chamber body 102 between a lower transfer portion and a number of raised process positions. Additionally, one or more lift pins 188 may be disposed through the support member 180. The one or more lift pins 188 are configured to extend through the support member 180 such that the substrate 101 may be raised off the surface of the support member 180. The one or more lift pins 188 may be active by a lift ring 190.

The processing chamber may also include a controller 191. The controller 191 includes programmable central processing unit (CPU) 192 that is operable with a memory 194 and a mass storage device, an input control unit, and a display unit (not shown), such as power supplies, clocks, cache, input/output (I/O) circuits, and the liner, coupled to the various components of the processing system to facilitate control of the substrate processing.

To facilitate control of the processing chamber 100 described above, the CPU 192 may be one of any form of general-purpose computer processor that can be used in an industrial setting, such as a programmable logic controller (PLC), for controlling various chambers and sub-processors. The memory 194 is coupled to the CPU 192 and the memory 194 is non-transitory and may be one or more of readily available memory such as random access memory (RAM), read only memory (ROM), floppy disk drive, hard disk, or any other form of digital storage, local or remote. Support circuits 196 are coupled to the CPU 192 for supporting the processor in a conventional manner. Charged species generation, heating, and other processes are generally stored in the memory 194, typically as software routine. The software routine may also be stored and/or executed by a second CPU (not shown) that is remotely located from the processing chamber 100 being controlled by the CPU 192.

The memory 194 is in the form of computer-readable storage media that contains instructions, that when executed by the CPU 192, facilitates the operation of the processing chamber 100. The instructions in the memory 194 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such non-transitory computer-readable storage media, when carrying computer-readable instructions that direct the functions of the methods described herein, are embodiments of the present disclosure.

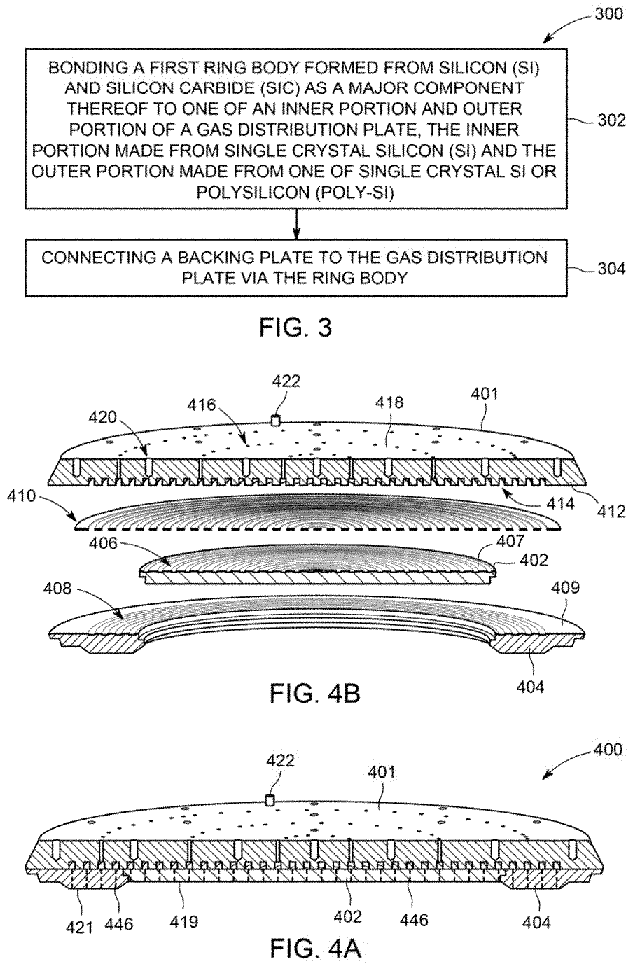

FIG. 2A is a side view of a gas distribution plate 138 and backing plate 139 of the showerhead assembly 150, and FIG. 3 is a flowchart of a method 300 of manufacture of the gas distribution plate 138 and backing plate 139 of FIGS. 2A-2C, according to at least some embodiments of the present disclosure. As noted above, the showerhead assembly 150 includes the gas distribution plate 138, the backing plate 139 positioned on a top surface of the gas distribution plate 138, and the chill plate 151 (not shown in FIGS. 2A-2C) positioned on a top surface of the backing plate 139. The gas distribution plate 138 includes an inner portion 202 having a top surface 204 and a bottom surface 206, which faces the processing region of the processing chamber 100. Similarly, an outer portion 208 of the gas distribution plate 138 includes a top surface 210 and a bottom surface 212, which faces the processing region of the processing chamber 100.

In at least some embodiments, the inner portion 202 and outer portion 208, when made from the same material (e.g., single crystal Si, poly-Si, etc.), can be monolithically formed (e.g., formed as a homogeneous unitary body). Alternatively or additionally, the inner portion 202 and outer portion 208 can be connected to each other via one or more suitable connection devices or methods. For example, in the illustrated embodiment, the inner portion 202 and outer portion 208 are connected to each other via a mechanical interface (e.g., corresponding indent/detent) that uses a press fit, so that the inner portion 202 and outer portion 208 can be interlocked to each other. One or more thermal gaskets, O-rings, or other suitable device(s) can be provided at the mechanical interface to ensure a seal is provided between the inner portion 202 and outer portion 208.

The inner portion 202 and the outer portion 208 can be made from one or more materials suitable for being bonded to one or more connectors 201. For example, the inner portion 202 and the outer portion 208 can be made from single crystal silicon (Si) and/or polysilicon (poly-Si). In at least some embodiments, the inner portion 202 can be made from single crystal silicon (Si) and the outer portion 208 made from one of single crystal Si or poly-Si.

The one or more connectors 201 are configured to be bonded to the inner portion 202 and/or the outer portion 208 of the gas distribution plate 138 and are configured to connect the gas distribution plate 138 to the backing plate 139, as will be described in greater detail below (see FIG. 3 at 302, for example). A bonding layer (not explicitly shown) can be organic bonding material or diffusion bonding material. For example, in at least some embodiments, the bonding layer can be made from one or more suitable materials capable of bonding the one or more connectors 201 to the to the inner portion 202 and/or the outer portion 208 of the gas distribution plate 138. For example, in at least some embodiments, the bonding layer can be made from Al, an aluminum silicon alloy (AlSi) material, and/or titanium (Ti). For example, the bonding material can comprise Al and/or AlSi and a percentage of Ti, e.g., from about 0.1% to about 10%. In at least some embodiments, the percentage of Ti can be about 2.5%. One or more thermal gaskets can be used in conjunction with bonding layer. A furnace process (e.g., vacuum furnace or other suitable type of furnace) can be used to bond the one or more connectors 201 to the inner portion 202 and/or the outer portion 208 of the gas distribution plate 138. For example, the furnace process can provide temperatures at about 550 degrees Celsius to about 600 degrees Celsius to the bonding layer. In at least some embodiments the bonding layer may have a thickness of about 2 microns to 40,000 microns. Additionally, the bonding process may have a dwell time of about 2 hours to about 4 hours and a cooling rate of about 3 K/min to about 7 K/min.

In at least some embodiments, the coefficient of thermal expansion (CTE) between the gas distribution plate 138 (e.g., Si) and the backing plate 139 (e.g., SiC) is about 2 to about 7, and in some embodiments is about 3.1 to about 3.3.

In at least some embodiments, the one or more connectors 201 includes one or more ring bodies (see FIGS. 2B and 2C), which can be bonded to the inner portion 202 and/or the outer portion 208. In the illustrated embodiment, an inner ring body 214 (e.g., a first ring body) extends from the top surface 204 of the inner portion 202. Additional ring bodies can be provided on the inner portion 202. The inner ring body 214 includes a stepped configuration (e.g., two steps) including a first step 216 and a second step 218 having a space or void 220 therebetween. Likewise, an outer ring body 222 (e.g., a second ring body) extends from the top surface 210 of the inner portion 202 and includes a stepped configuration (e.g., two steps) including a first step 224 and a second step 226 having a space or void 228 therebetween. Additional ring bodies can be provided on the inner portion 202 and/or the outer portion 208.

In at least some embodiments, only one of the inner portion 202 and the outer portion 208 can include a ring body. For example, in at least some embodiments, the inner portion 202 can be provided with a ring body and the outer portion 208 can be provided without a ring body, or vice versa.

Each of the inner ring body 214 and outer ring body 222 can be made from one or more materials suitable for being bonded to the inner portion 202 and the outer portion 208. For example, in at least some embodiments, each of the inner ring body 214 and outer ring body 222 can be made from materials having silicon (Si) at varying quantities with silicon carbide (SIC) as a major component thereof (e.g., SiSiC). Si content (volume %) of the ring bodies may be about 20 to about 30 with the remainder being SIC.

While the inner ring body 214 and outer ring body 222 are shown having a continuous or non-interrupted configuration along a circumference thereof, the present disclosure is not so limited. For example, in at least some embodiments, one or both of the inner ring body 214 and outer ring body 222 can have a discontinuous or interrupted configuration. In such embodiments, one or more gaps or spaces 223 can be provided along a circumference of the inner ring body 214 and/or outer ring body 222. For illustrative purposes, FIG. 2D shows a top portion of the inner ring 222 having a plurality of gaps 223 (e.g., four gaps 223).

Continuing with reference to FIGS. 2A-2C, a corresponding jacket 230, 232 made from one or more suitable materials covers the inner ring body 214 and the outer ring body 222. The jackets 230, 232 can be made from Al, stainless steel, SiC, aluminum nitride (AlN), and the like. For example, in the illustrated embodiments, the jackets 230, 232 are made from Al.

The jackets 230, 232 are configured to couple to the corresponding inner ring body 214 and outer ring body 222 via a mechanical interface. For example, the ring body 214 and outer ring body 222 have one or more features formed therein and the jackets 230, 232 have one or more corresponding mating (interlock) features that lock the ring body 214 and outer ring body 222 to the jackets 230, 232, thus preventing separation thereof when assembled. For example, in at least some embodiments, the jackets 230, 232 include a corresponding stepped configuration. The corresponding stepped configuration allows coupling of the jackets 230, 232 to the corresponding inner ring body 214 and outer ring body 222 via a press fit (e.g., interlocked to each other), see indicated areas of detail 234, 236 of FIG. 2B, for example.

Disposed along a top surface 238, 240 of the jackets 230, 232 are a plurality of threaded apertures 242 that are configured to receive a corresponding plurality of threaded screws or bolts (not shown). The plurality of screws or bolts are driven through a corresponding plurality of apertures 244 that extend through a top surface 246 of the backing plate 139 for connecting the backing plate 139 to the gas distribution plate 138 (see FIG. 2A, for example). More particularly, the apertures 244 are vertically aligned with annular grooves 248 (FIG. 2A) defined in a bottom surface 249 of the backing plate 139. The annular grooves 248 correspond to the ring bodies (e.g., inner ring body 214 and outer ring body 222) on the inner portion 202 and outer portion 208 and are configured to receive the ring bodies. Once received, the plurality of threaded screws or bolts are driven through the apertures 244 of the backing plate 139 and into the threaded apertures 242 of the jackets 230, 232 to connect the gas distribution plate 138 to the backing plate 139 (see FIG. 3 at 304, for example).

One or more temperature detection assemblies 250 (FIGS. 2A and 2B) can be coupled to the gas distribution plate 138, e.g., on a top surface of the inner portion 202 and outer portion 208, for example, using one of the above described bonding processes. For illustrative purposes, a temperature detection assembly 250 is shown coupled to the top surface 204 of the inner portion 202. The temperature detection assembly 250 is configured to monitor a temperature of the gas distribution plate 138 during processing. For a more detailed description of the temperature detection assembly 250 and monitoring processes used therewith, reference is made to U.S. Patent Publication 20180144907, entitled “THERMAL REPEATABILITY AND IN-SITU SHOWERHEAD TEMPERATURE MONITORING,” assigned to Applied Materials, Inc, which is incorporated herein by reference in its entirety. The temperature detection assembly 250 is configured to be received within a corresponding aperture (not explicitly shown) defined within the bottom surface 249 of the backing plate 139 (see FIG. 2A, for example).

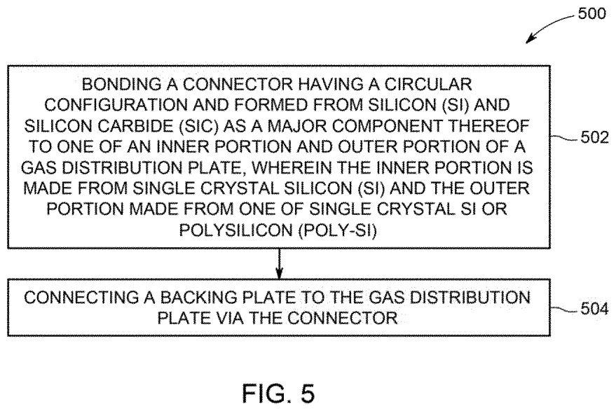

FIG. 4A is a side view of a gas distribution plate 400 configured for use with the showerhead assembly 150, FIG. 4B is an exploded view of the gas distribution plate 400 of FIG. 4A, and FIG. 5 is a flowchart of a method 500 of manufacture of the gas distribution plate and backing plate of FIGS. 4A-4B, according to at least some embodiments of the present disclosure. The gas distribution plate 400 is similar to the gas distribution plate 138. Accordingly, only those features unique to the gas distribution plate 400 are described herein.

The gas distribution plate 400 includes an inner portion 402 and an outer portion 404, which can be made from the same materials as described above with respect to the inner portion 202 and an outer portion 208. Unlike the inner portion 202 and an outer portion 208 of the gas distribution plate 138, however, one or both of the inner portion 402 and the outer portion 404 of the gas distribution plate 400 include a plurality of concentric grooves. In the illustrated embodiment, each of the inner portion 402 and the outer portion 404 includes a plurality of concentric grooves 406, 408, respectively, defined on a top surface 407 of the inner portion 402 and a top surface 409 of the outer portion 404. The concentric grooves 406, 408 are configured to receive a corresponding plurality of rings 410 used for bonding a connector 401 to the inner portion 202 and the outer portion 208. The rings 410 can be made from, for example, Al or an aluminum silicon alloy AlSi material.

Unlike the connector 201 that includes the ring bodies of FIGS. 2A-2C, the connector 401 of FIGS. 4A and 4B has a generally circular configuration and substantially covers one or both of the inner portion 402 and outer portion 404 of the gas distribution plate 400. For example, in some embodiments, the connector 401 can be disposed on only the inner portion 402. In some embodiments, the connector 401 can be disposed on only the outer portion 404. In the illustrated embodiment, the connector 401 is disposed on and extends from both the inner portion 402 and the outer portion 404.

A bottom surface 412 of the connector 401 is supported on the top surface 407 of the inner portion 402 and the top surface 409 of the outer portion 404, and atop the plurality of rings 410, e.g., for bonding the connector 201 to the inner portion 402 and outer portion 404, see FIG. 5 at 502.

One or more gas passages (or channels) 414 are defined in the connector 401 and extend to the bottom surface 412 thereof. The one or more gas passages 414 are in fluid communication with one or corresponding more apertures 416 defined through a top surface 418 of the connector 401 and a plurality of apertures 446 on a bottom surface 419 and a bottom surface 421 of the inner portion 402 and the outer portion 404, respectively, thus allowing process gas to flow from the backing plate 139, through the connector 401, and into the processing region.

A plurality of threaded apertures 420 are defined through the top surface 418 of the connector 401 and are configured to receive one or more corresponding screws or bolts to connect the gas distribution plate 400 to the backing plate 139, see FIG. 5 at 504. Additionally, one or more temperature detection assemblies 422 can be coupled to one or both of the inner portion 402 or outer portion 404 of the gas distribution plate 400, e.g., on a top surface 409 of the outer portion 404, using one of the above described bonding processes. The one or more temperature detection assemblies 422 can be received in a corresponding aperture on the backing plate 139.

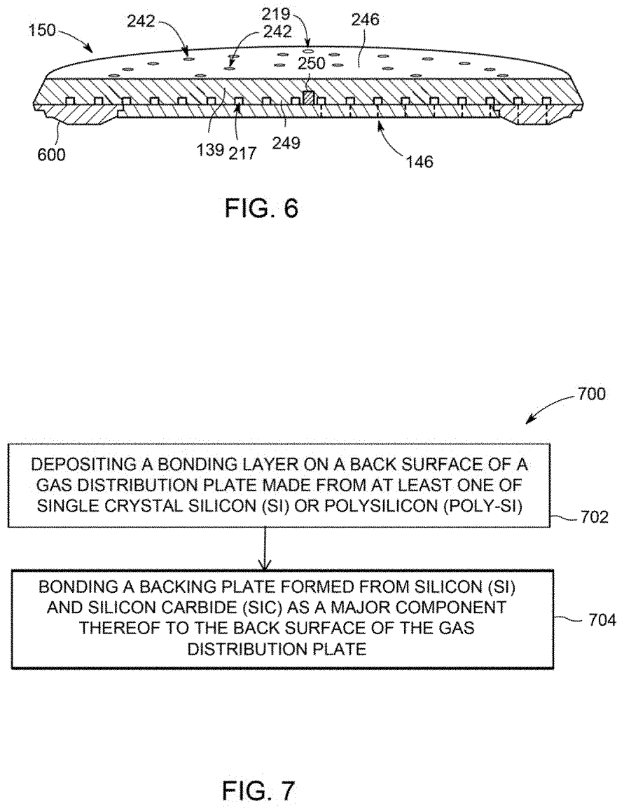

FIG. 6 is a side cutaway view of a gas distribution plate and backing plate of a showerhead assembly, and FIG. 7 is a flowchart of a method 700 of manufacture of the gas distribution plate and backing plate of FIG. 6, according to at least some embodiments of the present disclosure.

The gas distribution plate 600 is similar to the gas distribution plate 138. Accordingly, only those features unique to the gas distribution plate 600 are described herein.

Unlike the gas distribution plate 138, the gas distribution plate 600 does not include one or more of the above described connectors. Rather, the gas distribution plate 600 is directly connected to the backing plate 139. For example, in at least some embodiments, a bonding layer (e.g., a bonding layer including at least one of the plurality of rings 410 (FIG. 4B) and/or the bonding layer used to bond the one or more connectors 201 to the gas distribution plate 138) can be provided on a back surface (e.g., an inner portion and/or outer portion or a homogeneous unitary body) of the gas distribution plate 600, as described above with respect to FIGS. 2A-2D. Alternatively or additionally, one or more concentric grooves can be provided on the back surface (e.g., an inner portion and/or outer portion) of the gas distribution plate 600 and the bonding layer can include a corresponding concentric ring, as described above with respect to FIGS. 4A and 4B. In at least some embodiments, the bonding layer can be deposited on a bottom surface of the backing plate 139, or on both of the top surface of the gas distribution plate 600 and the bottom surface of the backing plate 139.

Accordingly, in at least some embodiments, at 702, a bonding layer can be deposited on a back surface of the gas distribution plate 600, which as noted above can be made from at least one of single crystal silicon (Si) or polysilicon (poly-Si). In at least some embodiments, for example, the bonding layer can be deposited using physical vapor deposition (PVD). An example of a PVD apparatus that can be used to deposit the bonding layer is the ENDURA® line of PVD apparatus (e.g., stand-alone or part of a cluster tool), available from Applied Materials, Inc., located in Santa Clara, Calif. The thickness of the bonding layer can be about 1 micron to about 100 micron. In at least some embodiments, for example, the thickness of the bonding layer can be about 50 microns.

Thereafter, a backing plate (e.g., the backing plate 139) can be positioned on the gas distribution plate 600 (or vice versa). For example, in at least some embodiments, the backing plate can be positioned to fully contact a back surface of the gas distribution plate 600 so that uniform and even loading is achieved across the gas distribution plate 600 and critical alignment thresholds are met,

At 704, the backing plate can be bonded to the back surface of the gas distribution plate 600, in a manner as described above. For example, the furnace process can provide temperatures from about 350 degree Celsius to about 750 degrees Celsius, e.g., just below a eutectic point. In at least some embodiments, the furnace time can be relatively short. In at least some embodiments, a back-flow gas, such as nitrogen (N), argon (Ar), or other suitable back flow gas, can be introduced (e.g., during the furnace process) as the backing plate is being bonded to the gas distribution plate 600.

In at least some embodiments, prior to bonding the backing plate to the back surface of the gas distribution plate 600, a hard mask layer can be deposited on the back surface of the gas distribution plate 600. For example, in at least some embodiments, a hard mask layer made from polyimide can be deposited on the back surface of the gas distribution plate 600 using, for example, physical vapor deposition (PVD). Alternatively or additionally, the hard mask layer can be applied on the backing plate 139 (e.g., when the bonding layer is deposited on the backing plate). An example of a PVD apparatus that can be used to deposit the hard mask layer is the ENDURA® line of PVD apparatus (e.g., stand-alone or part of a cluster tool), available from Applied Materials, Inc., located in Santa Clara, Calif. The hard mask layer can be used to cover/shield the apertures (e.g., apertures 146)—and/or portions of the back surface—of the gas distribution plate 600 so that the apertures are not filled by the bonding material used to form the bonding layer during PVD. After the bonding layer is deposited on the back surface of the gas distribution plate 600, the hard mask layer can be removed using one or more suitable processes, such as the etching process described above.

After 704, one or more processes (e.g., measurement techniques) can be used to examine the bond between the gas distribution plate 600 and the backing plate. For example, in at least some embodiments, scanning acoustic microscopy (SAM) metrology or other suitable measurement techniques such as sonar scanning and/or sonar imaging can be used to examine the bond between the gas distribution plate 600 and the backing plate. Additionally, after 704 one or more suitable cleaning processes can be used to provide a final cleaning of the gas distribution plate 600 and the backing plate bonded thereto (e.g., an assembled showerhead). For example, in at least some embodiments, an etching process can be used to clean the assembled showerhead.

As noted above, removing a gas distribution plate may prove advantageous, such as after extended use thereof. Accordingly, in at least some embodiments, the method 700 can include removing the gas distribution plate 600 from the backing plate and installing a new gas distribution plate. The gas distribution plate can be removed using one or more suitable removal processes. For example, one or more chemical solutions can be used to remove the bonding layer between the gas distribution plate 600 and the backing plate. In at least some embodiments, for example, a low concentration of hydrochloric acid (HCl) can be used to separate the gas distribution plate 600 and the backing plate from each other.

Once the gas distribution plate 600 and the backing plate are separated, the method 700 can include cleaning the backing plate using, for example, one or more cleaning processes, such as chemical-mechanical polishing (CMP), etching, etc. For example, in at least some embodiments, CMP can be used to clean the bottom surface backing plate (e.g., the surface that will be bonded to a new gas distribution plate.

Thereafter, the new gas distribution plate can be reattached to the backing plate, using, for example, one or more of the processes described with respect method 700.

While the foregoing is directed to embodiments of the present disclosure, other and further embodiments of the disclosure may be devised without departing from the basic scope thereof.

1. A showerhead assembly, comprising:
a gas distribution plate comprising an inner portion and an outer portion, the inner portion made from single crystal silicon (Si) and the outer portion made from one of single crystal Si or polysilicon (poly-Si), wherein a bonding layer is provided on a back surface of at least one of the inner portion or outer portion; and
a backing plate formed from silicon (Si) and silicon carbide (SiC) as a major component thereof, wherein the backing plate is bonded to at least one of the back surface of at least one of the inner portion or outer portion of the gas distribution plate.

2. The showerhead assembly of claim 1, wherein the inner portion and outer portion are a homogeneous unitary body made from single crystal silicon Si.

3. The showerhead assembly of claim 1, wherein the bonding layer includes at least one concentric ring seated within a corresponding concentric groove on the back surface of at least one of the inner portion or outer portion.

4. The showerhead assembly of claim 1, wherein the bonding layer is made of aluminum silicon alloy or aluminum, with a percentage of titanium (Ti).

5. The showerhead assembly of claim 4, wherein the percentage of Ti ranges from about 0.1% to about 10%.

6. The showerhead assembly of claim 1, wherein a coefficient of thermal expansion (CTE) between the gas distribution plate and the backing plate is about 2 to about 7.

7. A process chamber, comprising:
a showerhead assembly, comprising:
a gas distribution plate comprising an inner portion and an outer portion, the inner portion made from single crystal silicon (Si) and the outer portion made from one of single crystal Si or polysilicon (poly-Si), wherein a bonding layer is provided on a back surface of at least one of the inner portion or outer portion; and
a backing plate formed from silicon (Si) and silicon carbide (SiC) as a major component thereof, wherein the backing plate is bonded to at least one of the back surface of at least one of the inner portion or outer portion of the gas distribution plate.

8. The process chamber of claim 7, wherein the inner portion and outer portion are a homogeneous unitary body made from single crystal silicon Si.

9. The process chamber of claim 7, wherein the bonding layer includes at least one concentric ring seated within a corresponding concentric groove on the back surface of at least one of the inner portion or outer portion.

10. The process chamber of claim 7, wherein the bonding layer is made of aluminum silicon alloy or aluminum, with a percentage of titanium (Ti).

11. The process chamber of claim 10, wherein the percentage of Ti ranges from about 0.1% to about 10%.

12. The process chamber of claim 7, wherein a coefficient of thermal expansion (CTE) between the gas distribution plate and the backing plate is about 2 to about 7.

13. A method of forming a showerhead assembly, comprising:
depositing a bonding layer on a back surface of a gas distribution plate made from at least one of single crystal silicon (Si) or polysilicon (poly-Si); and
bonding a backing plate formed from silicon (Si) and silicon carbide (SiC) as a major component thereof to the back surface of the gas distribution plate.

14. The method of claim 13, wherein the gas distribution plate comprises an inner portion and outer portion, and wherein the inner portion and outer portion are a homogeneous unitary body made from single crystal silicon Si.

15. The method of claim 14, wherein the bonding layer includes at least one concentric ring seated within a corresponding concentric groove on the back surface of at least one of the inner portion or outer portion.

16. The method of claim 13, wherein the bonding layer is made of aluminum silicon alloy or aluminum, with a percentage of titanium (Ti).

17. The method of claim 16, wherein the percentage of Ti ranges from about 0.1 to about 10%.

18. The method of claim 13, further comprising performing at least one of scanning acoustic microscopy (SAM) metrology, sonar scanning, or sonar imaging to examine the bond between the gas distribution plate and the backing plate.

19. The method of claim 13, wherein bonding the backing plate to the back surface of the gas distribution plate comprises using a furnace process that provides temperatures from about 350 degree Celsius to about 750 degrees Celsius.

20. The method of claim 19, further comprising introducing a back-flow gas while performing the furnace process.
